(19) United States
(12) Patent Application Publication
(10) Pub. No.: US 2012/0103404 A1
(43) Pub. Date: May 3, 2012

(54) QUANTUM DOT SENSITIZED SOLAR CELL

(75) Inventors: Nobuhiro Fuke, Los Alamos, NM (US); Alexey Y. Koposov, Los Alamos, NM (US); Milan Sykora, Los Alamos, NM (US); Laura B. Hoch, Toronto (CA); Virginia W. Manner, Los Alamos, NM (US)

(73) Assignee: LOS ALAMOS NATIONAL SECURITY, LLC, Los Alamos, NM (US)

(21) Appl. No.: 13/274,675

(22) Filed: Oct. 17, 2011

Related U.S. Application Data
(60) Provisional application No. 61/393,768, filed on Oct. 15, 2010.

(51) Int. Cl. H01L 31/0725; H01L 29/66

(52) U.S. Cl. 136/255; 257/22; 257/E29.168

(57) ABSTRACT

Photoelectrochemical solar cells (PECs) consisting of a photoanode were prepared by direct deposition of independently synthesized CdSe nanocrystal quantum dots (NQDs) onto a nanocrystalline TiO₂ film (NQD/TiO₂), aqueous Na₂S or Li₂S electrolyte and a Pt counter electrode. The light harvesting efficiency (LHE) of the NQD/TiO₂ photoanode is significantly enhanced when the NQD surface passivation is changed from tri-n-octylphosphine oxide (TOPO) to a smaller ligand (e.g. n-butylamine (BA)). Using NQDs with a shorter passivating ligand, BA, leads to a significant enhancement in both the electron injection efficiency at the NQD/TiO₂ interface and charge collection efficiency at the NQD/electrolyte interface, with the latter attributed mostly to a more efficient diffusion of the electrolyte through the pores of the photoanode. By utilizing BA capped NQDs and aqueous Li₂S as an electrolyte, it is possible to achieve about 100% internal quantum efficiency of photon-to-electron conversion, matching the performance of dye sensitized solar cells.

### RELATED APPLICATIONS

This application claims the benefit of U.S. Provisional Patent Application 61/393,768 filed Oct. 15, 2010, which is incorporated by reference herein.

### STATEMENT REGARDING FEDERAL RIGHTS

This invention was made with government support under Contract No. DE-AC52-06NA25396 awarded by the U.S. Department of Energy and made under CRADA number LA08C10583 with the SHARP Corporation. The government has certain rights in the invention.

### FIELD OF THE INVENTION

The invention relates to solar cells. More particularly, the invention relates to quantum dot sensitized solar cells.

### BACKGROUND OF THE INVENTION

Photoelectrochemical cells (PECs) based on a mesoporous nanocrystalline TiO₂ film (TiO₂ film) sensitized with organic or organometallic dyes have been studied intensely for the past twenty years as a potential low cost alternative to more traditional, solid state photovoltaics. Significant progress has been made in optimization of the components of the dye sensitized solar cell (DSSC) with highest reported efficiencies currently exceeding 11%. As part of search for new approaches to further improvement in efficiency over past several years, a number of research groups reported studies of PECs in which the sensitizing dyes are substituted with semiconductor nanocrystalline quantum dots (NQDs) of materials such as InP, CdS, CdSe, CdTe, PbS and InAs. In these studies it was demonstrated that semiconductor NQDs can function as efficient sensitizers across a broad spectral range from the visible to mid-infrared, and offer advantages such as the tunability of optical properties and electronic structure by simple variation in NQD size, while retaining the appeal of low-cost fabrication.

Two distinct approaches to the sensitization of TiO₂ with narrow band gap semiconductors have been demonstrated in recent studies. In one approach, semiconductor NQDs are generated on the surface of TiO₂ films in-situ, using chemical bath deposition (CBD) or successive ionic layer adsorption and reaction (SILAR). The advantage of the in-situ deposition approaches are their simplicity, the fact that the NQDs are in direct electronic contact with TiO₂, and that they can easily produce TiO₂ films with high surface coverage of the sensitizing NQDs. However, there are several limitations of the in-situ approaches, such as poor control over NQDs chemical composition, crystallinity, size and surface properties, which may hamper effective exploitation of the advantages of the NQDs.

An alternative approach is based on a two step process, whereby NQDs are first independently synthesized with a layer of organic ligands, such as tri-n-octylphosphine oxide (TOPO), aliphatic amines, or acids using established colloidal synthesis methods, and the TiO₂ film is subsequently sensitized by exposure to a solution of the NQDs. The advantage of this approach is a better control over the chemical, structural and electronic properties of the NQDs compared to the in-situ approaches. Several groups have demonstrated that exposure of “bare” TiO₂ films or TiO₂ films functionalized with bifunctional organic linkers (i.e., organic molecules containing functional groups for chemical attachment to TiO₂ and NQD surfaces) to solutions of NQDs leads to their effective sensitization, and device performance is better without linkers than with linkers. While in the studies of PEC performance, several parameters, such as NQD size, and counter electrode material have been evaluated, the NQD organic surface passivation, however, remained mostly unexplored.

### SUMMARY OF THE INVENTION

The present invention provides for an article including a substrate, a metal oxide film on the substrate, nanocrystalline quantum dots on the metal oxide film, the nanocrystalline quantum dots further comprising ligands attached to the quantum dots, the ligands are primary amines having the formula RNH₂.

The present invention also provides for an article comprising a substrate; a metal oxide film on the substrate, quantum dots on the metal oxide film, the quantum dots further comprising ligands attached to the quantum dots, the ligands being primary amines having a size less than the size of tri-n-octylphosphine oxide.

The invention also includes a photoelectrochemical cell solar cell (PEC) comprising: a photoanode comprising an electrically conducting substrate; and a nanocrystalline film of a metal oxide on the electrically conducting substrate. The nanocrystalline film has a defined pore structure therein and further having pre-formed nanocrystalline quantum dots (NQD) within said pore structure. The pre-formed NQDs have an organic passivating ligands that are primary amines attached to the NQDs. The PEC also includes a counter electrode and an electrolyte in contact with both the photoanode and the counter electrode.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1 shows absorption spectra of CdSe NQDs (r ˜2.15 nm), with n-butylamine (BA) or tri-n-octylphosphine oxide (TOPO) passivation, deposited on TiO₂ films, (film thickness ˜5 μm) and suspended in hexane solution. The NQD/TiO₂ films were prepared by exposure of the TiO₂ film to 3.0×10⁻⁶M hexane solution of NQDs for 48 hours. Also shown is the absorption spectrum of the blank TiO₂ film. (b) Experimentally determined Light Harvesting Efficiency (LHE) for the two films shown in (a) compared with the TiO₂ film of the same thickness sensitized with an organometallic chromophore [cis-di(thiocyanato)-bis(2,2′-bipyridiyl-4,4′-dicarboxylate) ruthenium(II), Ru(dcbpy)₂(NCS)₂] known as N3 dye. The dotted lines represent the error of the measurement for the independently prepared films following the same procedure. The TiO₂ film sensitized with an N3 dye was prepared by exposure of the TiO₂ film to 0.3 M solution of the dye in ethanol for 48 hrs. (c) molar extinction coefficients of CdSe NQDs (TOPO) of various sizes compared with molar extinction coefficient of N3 dye. (d) Calculated LHE for the same series of CdSe NQDs (TOPO) as in (c) assuming size scaled surface coverage to be the same as for the N3 dye, shown as a dashed line. The dotted line represents calculated LHE for CdSe NQDs with BA as a passivating ligand

FIG. 2 shows the dependence of short circuit current on the intensity of light irradiation measured using n-butylamine (BA) capped (square) and tri-n-octylphosphine oxide (TOPO) capped (triangle) quantum dot sensitized solar cell with aqueous 1M Na₂S electrolyte. The straight line (solid line: BA, dotted line: TOPO) is a linear fit going from the origin to the first measurement result at the lowest light irradiation intensity. The area of the device was 0.2209 cm².

FIG. 3a shows a comparison of incident photon to current conversion efficiency (IPCE) for CdSe NQD/TiO₂ solar cells using NQDs with n-butylamine (BA) or tri-n-octylphosphine oxide (TOPO) as capping ligands. The electrolyte was in 1M Li₂S aqueous solution. FIG. 3b shows the dependence of IQE (internal quantum efficiency) calculated as: IQE=(IPCE/% T FTO)/% LHE. Inset: The experimental data used for calculation of IQE of the device shown in solid circles in the main panel. FIG. 3c shows the dependence of IPCE on various device preparation conditions. The absorption spectrum increases at all wavelengths due to the significant change in path length from a single-layer TiO₂ film to a double-layer film.

### DETAILED DESCRIPTION

The present invention is concerned with improvements in photoelectrochemical cells especially photoelectrochemical solar cells.

“Nanocrystalline quantum dot” it is meant to include nanocrystalline particles of all shapes and sizes. Preferably, they have at least one dimension less than about 100 nanometers, but they are not so limited. There may be rods may be of any length. “Nanocrystal”, “nanorod” and “nanoparticle” can and are used interchangeably herein. In some embodiments of the invention, the nanocrystal particles may have two or more dimensions that are less than about 100 nanometers. The nanocrystals may be core type or core/shell type or can have more complex structures. For example, some branched nanocrystal particles according to some embodiments of the invention can have arms that have aspect ratios greater than about 1. In other embodiments, the arms can have aspect ratios greater than about 5, and in some cases, greater than about 10, etc. The widths of the arms may be less than about 200, 100, and even 50 nanometers in some embodiments. For instance, in an exemplary tetrapod with a core and four arms, the core can have a diameter from about 3 to about 4 nanometers, and each arm can have a length of from about 4 to about 50, 100, 200, 500, and even greater than about 1000 nanometers. Of course, the tetrapods and other nanocrystal particles described herein can have other suitable dimensions. In embodiments of the invention, the nanocrystal particles may be single crystalline or polycrystalline in nature. The invention also contemplates using nanorods of CdSe and CdTe that have aspect ratios above 20, even up to 50, and lengths greater than 100 nm, formed according to processes described in the literature, see Peng, X. G. et al. Nature 404, 59 (2000) and Peng, Z. A. et al. J. Am. Chem. Soc. 123, 183 (2001)

The nanocrystalline quantum dots of the present invention are generally referred to as colloidal nanocrystal quantum dots. These colloidal nanocrystal quantum dots can be of a single material or can comprise an inner core and an outer shell. The outer shell comprises an inorganic material, and in one embodiment may consist essentially of an inorganic material. The shape of the colloidal nanocrystal quantum dots may be a sphere, a rod, a disk, and combinations thereof, and with or without faceting. In one embodiment, the colloidal nanocrystal quantum dots include a core of a binary semiconductor material, e.g., a core of the formula MX, where M can be cadmium, zinc, indium, or alloys thereof and X is sulfur, selenium, tellurium, nitrogen, phosphorus, arsenic, antimony or mixtures thereof. In another embodiment, the colloidal nanocrystal quantum dots include a core of a ternary semiconductor material, e.g., a core of the formula M₁M₂X, where M₁ and M₂ can be cadmium, zinc, indium, and mixtures or alloys thereof and X is sulfur, selenium, tellurium, nitrogen, phosphorus, arsenic, antimony or mixtures thereof. In another embodiment, the core of the colloidal nanocrystal quantum dots comprises a quaternary semiconductor material, e.g., of the formula M₁M₂M₃X, where M₁, M₂ and M₃ can be cadmium, zinc, indium and X is sulfur, selenium, tellurium, nitrogen, phosphorus, arsenic, antimony or mixtures thereof. Non-limiting examples of suitable core materials include cadmium sulfide (CdS), cadmium selenide (CdSe), cadmium telluride (CdTe), zinc sulfide (ZnS), zinc selenide (ZnSe), zinc telluride (ZnTe), indium arsenide (InAs), indium nitride (InN), indium phosphide (InP), indium antimonide (InSb), zinc cadmium selenide (ZnCdSe₂), and the like, mixtures of such materials, or any other semiconductor or similar materials. Preferably, the core material is selected from the group consisting of InP, InAs, InSb, CdS, CdSe, CdTe, and combinations thereof, and even more preferably the core material is CdSe.

The core material is chosen for it property of having a surface suitable for the binding of primary amine ligands.

Some embodiments of the invention employ relatively short ligands upon the quantum dot. Among such ligands can be included at least one of allylamine, propylamine, butylamine, pentylamine, hexylamine, heptylamine, octylamine, aniline, and benzylamine. Butylamine is a preferred amine.

The metal oxide comprises a transition metal. The metal oxide may be a mixed metal oxide. The metal oxide may include a dopant. Examples of suitable metal oxides include, but are not limited to, titanium oxide (TiO₂), tin oxide (SnO₂), zinc oxide (ZnO), tungsten oxide (WO₃), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃). The structure of metal oxide film may be, but is not limited to, a thin film, a nanotube or nanorod. The metal oxide may be nanocrystalline.

By photoelectrochemical cell (PEC) is meant to include those typical device architectures known in the art. Exemplary PEC devices are described in, for example, O'Reagan et al., Nature, Vol. 353, pp. 737-740, Oct. 24, 1991 the contents of which are incorporated by reference.

The electrolyte in the solar cells of the present invention are generally an aqueous solution of a sulfide such as lithium sulfide (Li₂S), sodium sulfide (Na₂S) potassium sulfide, rubidium sulfide, and cesium sulfide. Lithium sulfide and sodium sulfide are preferred as aqueous electrolytes.

The NQDs used herein were synthesized and purified following a standard literature procedure of Murray et al., Synthesis and Characterization of Nearly Monodisperse CdE (E=S, Se, Te) Semiconductor Nanocrystallites, J. Am. Chem. Soc., 1993, 115, 8706-8715, such reference incorporated herein by reference. The CdSe NQD/TiO₂ composite films were prepared by direct deposition of NQDs onto freshly prepared nanocrystalline TiO₂ films (TiO₂ films) from hexane or toluene solution.

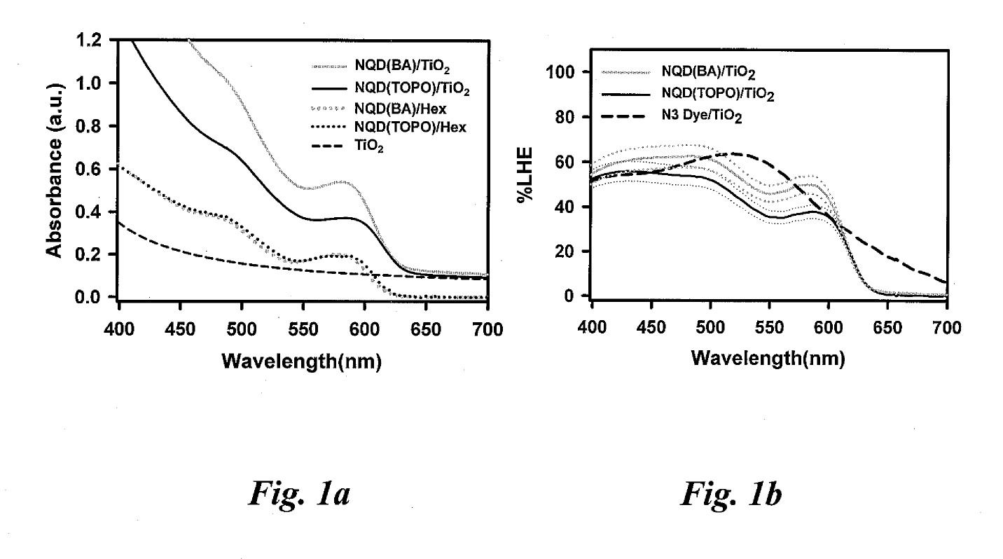

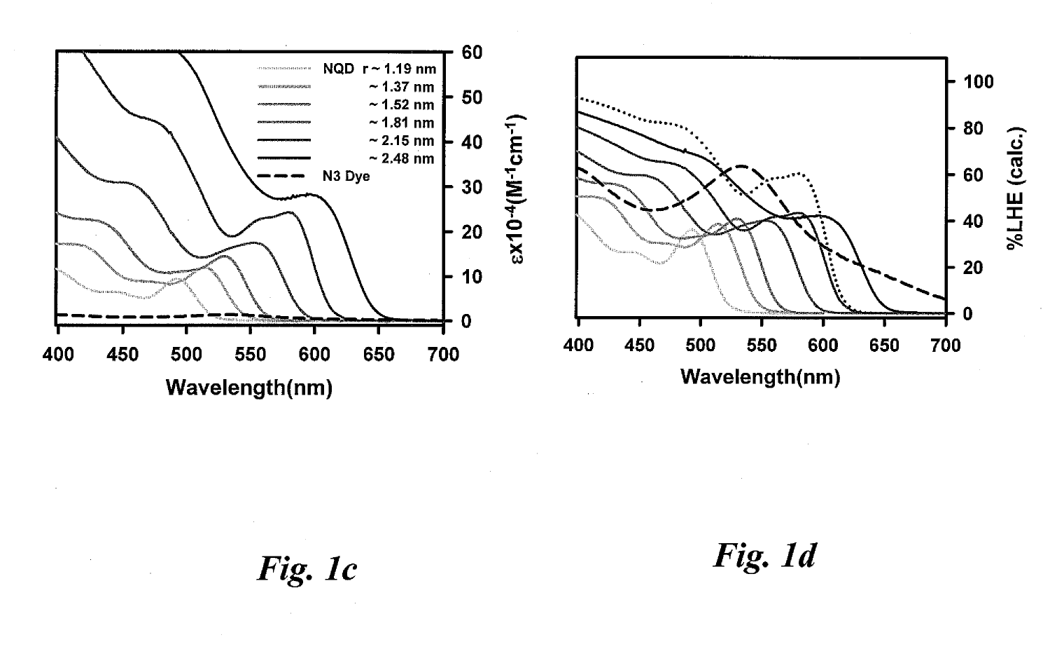

Optical studies of NQD/TiO₂ films revealed that the amount of NQDs deposited within the TiO₂ film is significantly affected by the type of NQD surface passivation (see FIGS. 1a, 1b). FIG. 1a compares absorption spectra of CdSe NQD/TiO₂ films prepared using NQDs capped with TOPO and films prepared using NQDs capped with BA. The BA-capped CdSe NQDs (NQD(BA)) were prepared from the same batch of TOPO-capped CdSe NQDs (NQD(TOPO)) by sequential precipitation in MeOH and dissolution of NQDs in n-butylamine at elevated temperature (see methods section for details). Also included in FIG. 1a are absorption spectra of the same NQDs in hexane solution and the absorption spectrum of the TiO₂ film. Comparison of the spectral features indicates that the modification of surface passivation or adsorption of NQDs into the TiO₂ film does not significantly alter their electronic structure. However, for NQD(BA) there has been a consistent observation of significantly higher optical densities of the NQD/TiO₂ films. This is consistent with the results of Light Harvesting Efficiency (LHE) measurements summarized in FIG. 1b, showing clear enhancement of LHE for the NQD(BA). Also included in FIG. 1b is the LHE of a TiO₂ film sensitized with an organometallic chromophore [cis-di(thiocyanato)-bis(2,2′-bipyridiyl-4,4′-dicarboxylate) ruthenium(II), Ru(dcbpy)₂(NCS)₂], known as N3 dye. An analysis of the LHE values for the N3/TiO₂, NQD(TOPO)/TiO₂ and NQD(BA)/TiO₂ provides important insights about the effect of the NQD surface passivation on the optical properties of the NQD/TiO₂ films

As a first step in the analysis, the experimentally determined molar extinction coefficient of N3 dye was compared with the estimated molar extinction coefficients of CdSe NQDs. As was previously known, the size dependent absorption cross sections of CdSe NQDs at 400 nm can be estimated using an empirical relationship σₒ(cm²)=(n_{CdSe}/nₛₒₗᵥₑₙₜ)1.6×10⁻¹⁶ [R(nm)]³, where σₒ is an absorption cross section, n_{CdSe} and nₛₒₗᵥₑₙₜ are refractive indexes of CdSe NQD (taken as 2.5) and solvent (nₕₑₓₐₙₑ=1.354) and R is the NQD radius. The radius of an NQD can be estimated from the absorption spectrum of the NQD solution using an empirical relationship between the NQD size and its band gap, typically taken as the peak of the lowest energy electronic transition (1 s). To convert the calculated value of σₒ(cm²) to molar extinction coefficient, ε (M⁻¹ cm⁻¹), the relationship ε=σₒN_{A}/(1000*2.303)=σₒ*2.61×10²⁰, where N_{A} is the Avogadro's constant, was used. The comparison of calculated values of ε for CdSe NQDs of several sizes and the molar extinction coefficient of N3 dye shows that on a molar basis NQDs are significantly better absorbers than the dye (FIG. 1c). This feature makes NQDs a very appealing alternative to molecular dyes as the sensitizer in PECs. However, since NQDs are typically much larger than molecular dyes, the amount of NQDs adsorbed per unit of TiO₂ surface area can be significantly smaller than that of dyes. Therefore the comparison of LHEs in composites with similar chromophore surface coverage is more useful from the practical standpoint

As was shown was shown previously by Argazziet al., Enhanced Spectral Sensitivity from Ruthenium(II) Polypyridyl Based Photovoltaic Devices, Inorg. Chem. 1994, 33, 5741-5749, in cases when the scattering and the reflectance are small compared to the absorption losses, the LHE is directly related to the molar extinction coefficient of a chromophore as shown in the Equation (1)

LHE(λ)=1−10^{-[1000(cm}^{³}^{L}^{^{−1}}^{)ε(mol}^{^{−1}}^{·L·cm}^{^{−1}}^{)Γ(mol·cm}^{^{−1}}^{)]} (1)

In Eq. (1) the ε is a molar extinction coefficient and Γ is the chromophore surface coverage in mol/cm². The calculated LHE for the N3 Dye is shown as a dashed line in FIG. 1d. In the calculation the surface coverage value was adjusted so as to match the calculated value of LHE (535 nm) with the experimentally observed value of LHE (535 nm) for N3 dye, shown in FIG. 1d. (Note that the experimentally observed LHE is broadened and partially distorted at high energies due to high TiO₂ absorption). To estimate the maximum achievable LHE by NQDs under the same conditions the NQD surface coverage was scaled using the relationship Γ_{NQD}=Γ_{N3}(S_{N3}/S_{NQD}), where S_{N3} and S_{NQD} are cross-sectional surface areas of N3 Dye and the NQDs, respectively. Each value is calculated as S=π×r², where r_{N3} was taken as 0.58 nm and r_{NQD} was taken as the radius of the NQD plus the length of the ligand (estimated as 1.1 nm for TOPO and 0.4 nm for BA). In this calculation it is assumed that the capping ligands are “impenetrable”; i.e., the periphery-to-periphery distance between the NQDs is equal to twice the ligand length. The results of the calculation for TOPO capped NQDs of several sizes are shown in FIG. 1d in solid lines. Also, shown is the result of a calculation for the NQDs with a particle radius of 2.15 nm, capped with BA (dotted line).

The results of the LHE calculations in FIG. 1d and their comparison with the experimental LHE shown in FIG. 1b lead to several observations. First, after accounting for their size, in spite of significantly higher molar extinction coefficients of NQDs compared to N3 dye, NQDs are not significantly better absorbers than molecular dyes, at least at energies close to the band edge. Second, both the theoretical analysis (FIG. 1d) and the experiment (FIG. 1b) indicate that reduction in length of the NQD capping ligand can significantly improve the LHEs of the NQD/TiO₂ films. Finally, the high LHEs observed experimentally for the NQDs suggest that they effectively cover the TiO₂ surface.

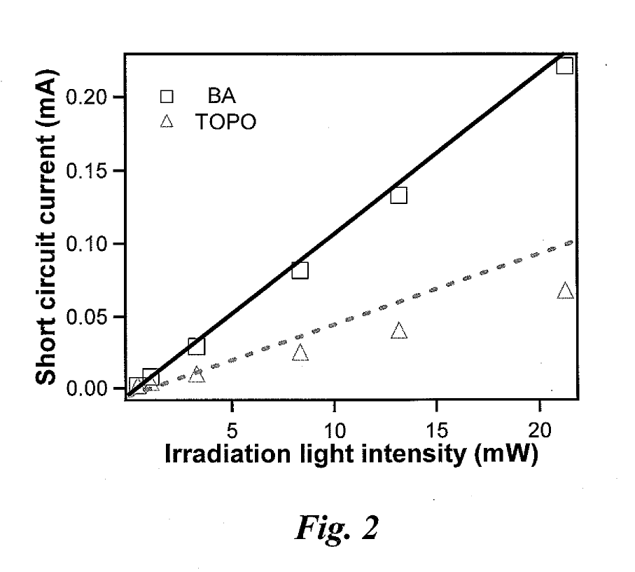

Effect of surface Effect of surface passivation on short-circuit current and mass transport in CdSe NQD/TiO₂ PEC. In FIG. 2 is shown experimentally observed short circuit current (I_{sc}) versus irradiation light intensity for two CdSe NQD/TiO₂ PECs prepared under identical conditions, differing only in the type of NQD capping layer. In one group of devices NQDs capped with TOPO were used and in the second the TOPO capping layer was substituted with BA prior to the device fabrication (see methods section for details). In both groups of devices a nearly linear increase in I_{sc} with increase in irradiation intensity was observed, which is expected according to Eq. 2.

$${I}_{sc} ( mA ) = {\int }_{λ} {I}_{0} ( mW ) \frac{λ ( nm )}{1240 eV \text{/} nm} I P C E ( λ ) d λ \\ wherein \\ I P C E ( λ ) = \% T ( λ ) ( substrate ) \times L H E ( λ ) \times {φ}_{inj} \times {φ}_{coll} \qquad ( 2 )$$

In Eq. 2, I₀ is the incident light intensity at wavelength λ, % T(λ)(substrate) is the transmittance of the substrate at the incident wavelength, φᵢₙⱼ is the electron injection efficiency, and φ_{coll} is the charge collection efficiency including contributions from electron transport in the TiO₂ film and the redox couple mediated hole transport between the sensitizer and the counter electrode.

In spite of the similarities in the overall trend of the I_{sc} dependence on light intensity in the two devices, there are some notable differences. The most apparent is the disparity in the absolute values of I_{sc} at all irradiation intensities, with significantly higher I_{sc}'s observed for NQD(BA). Consistent with Eq. 2 and with the results shown in FIG. 1b, part of the enhancement can be attributed to the increase in LHEs of the NQD(BA)/TiO₂ films compared to NQD(TOPO)/TiO₂ films. Enhancement in I_{sc} due to better infiltration of NQDs into TiO₂ films with larger pore sizes was previously reported by Giménez et. al. “Improving the Performance of Colloidal Quantum-Dot-Sensitized Solar Cells”, Nanotech. 2009, 20, 295204, However, while the TOPO-to-BA substitution leads to ˜40% enhancement in LHE at the is peak (FIG. 1b), the enhancement in I_{sc} is approximately four fold (FIG. 2). This indicates that there is an additional factor, besides LHE, that contributes to the I_{sc} enhancement in NQD(BA)-based devices. While not wishing to be bound by the present explanation, it is believed that the I_{sc} enhancement in NQD(BA) devices is associated with enhancement in charge collection efficiency, whereby the use of shorter BA ligands allows better diffusion of electrolyte through the pores of the NQD/TiO₂ film as well as better access of S²⁻ to the NQD surface. This belief is supported by the observed deviation of the experimental values of I_{sc}, indicated by open squares and open triangles for NQD(BA) and NQD(TOPO) respectively, from the line drawn between the axes origin and the first experimental data point observed at the lowest irradiation intensity. In the case of the NQD(BA) the deviation between the experimental points and the linear line is very small, indicating that charge collection efficiencies are not subject to mass transport limitations even at high light intensities. However, for the NQD(TOPO)-based devices the experimental short circuit current values clearly deviate from the linear plot at high light intensities, suggesting increasing mass transport limitations, which were attributed to restricted electrolyte diffusion and NQD surface accessibility.

Effect of electrolyte and extent of NQD adsorption on the IPCE. Consistent with the results of short circuit current measurements in FIG. 2, it was found that measured IPCEs are significantly smaller for NQD (TOPO) than NQD (BA). For the NQD (BA) it was found that the IPCE increases with the concentration of the NQD solution, which is attributed to the enhancement in the LHE.

Determination of Internal Quantum Efficiency (IQE) for the CdSe NQD/TiO₂ PEC. IQE is an important characteristic of a PEC, indicating how efficiently the absorbed (rather than incident) photons are converted to current in the external circuit. The IQE of the PEC can be estimated from experimentally determined IPCE and LHE, after accounting for losses due to light absorption by the FTO substrate, according to Eq. (3).

IQE=IPCE/(% T(FTO)×LHE)=φᵢₙⱼ×φ_{coll} (3)

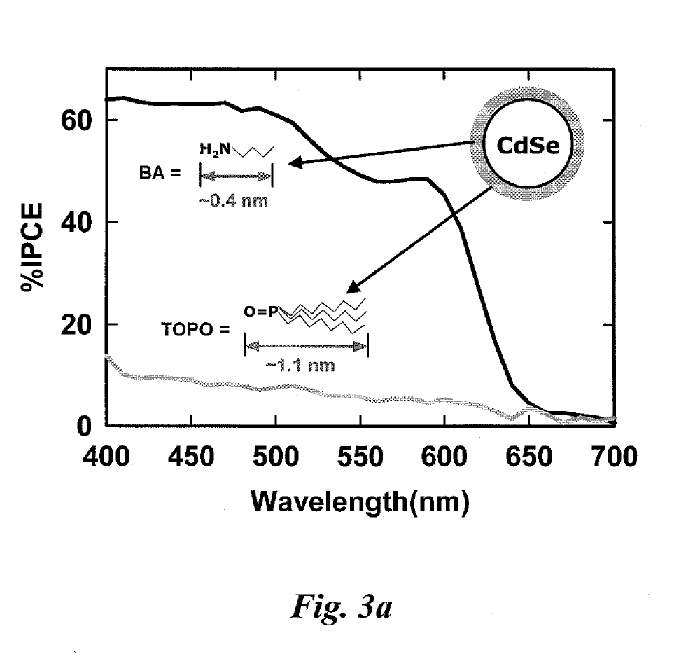

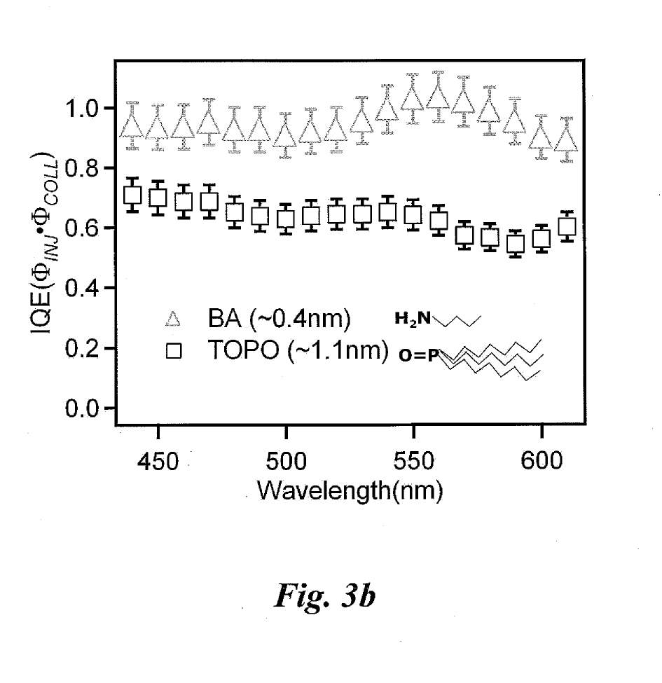

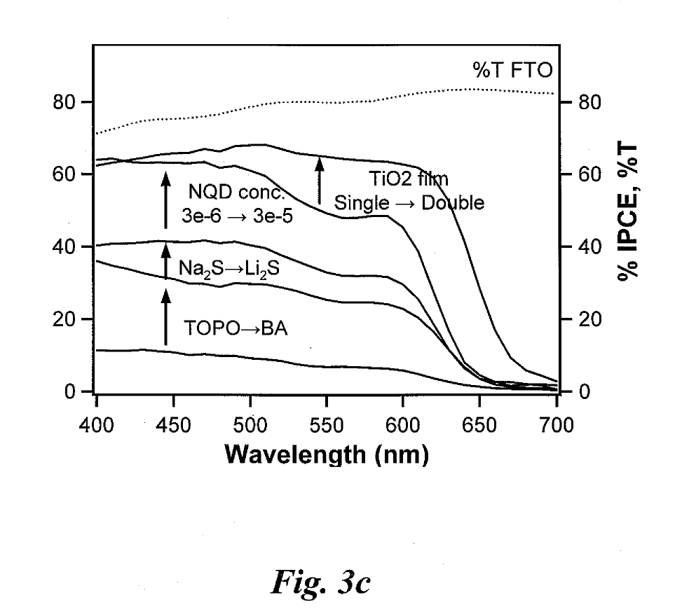

The results of the IQE analysis for the NQD(BA)/TiO₂ and NQD(TOPO)/TiO₂ device prepared using 3×10⁻⁶ M NQD solution and 1M aqueous Li₂S as an electrolyte are shown in FIG. 3b. It is noted that the measurement of the IPCE was performed on a PEC device, and the measurement of LHE was performed on TiO₂/NQD film prepared under identical conditions, but in the absence of electrolyte. The results of the analysis show that the IQE for NQD(BA)/TiO₂ is higher than NQD(TOPO)/TiO₂. As implied by Eq. 3 the IQE results indicate that both electron injection and charge collection efficiencies are higher using NQD(BA)/TiO₂ than with NQD(TOPO)/TiO₂.

Effect of TiO₂ film structure on the IPCE. To further improve the IPCE of NQD PECs a series of devices using a double layer TiO₂ film structure were fabricated consisting of a bottom (in contact with FTO) light absorption layer (about 5 micrometer (um) with 20 nm particles) and a top light scattering layer (about 5 um with 400 nm particles). This type of structure is commonly used to enhance the LHEs of DSSCs. The results of the IPCE study of the double layer structure compared with different configurations of monolayer devices, using the same size of NQDs (1 s at 590 nm; r ˜2.3 nm) are shown in FIG. 3c. The results clearly show enhancement in the IPCE of the double layer device for all wavelengths above 450 nm, which is attributed to the scattering-induced increase in the path length of the incident light.

Synthesis and purification of CdSe NQDs. The TOPO capped NQDs were synthesized and purified following the standard literature procedure of Murray as noted above. All the synthetic and purification steps were performed under argon atmosphere and the product was stored in argon filled glove box until use.

NQD ligand exchange. All the operations were performed in glove box under argon. The NQD growth solution (1 g) was dissolved in 1.5 mL of hexane at 35° C. To this solution, 8-10 mL MeOH was added to precipitate the NQDs. The solution was centrifuged and decanted, and the decanted NQDs were dissolved in 0.5 mL of n-butylamine. This solution was heated for 40-60 minutes at 55° C., poured into a centrifuge tube, and precipitated with 5 mL MeOH. The solution was centrifuged and decanted, and the precipitate redissolved in 1.2 mL n-butylamine. The solution was again heated, for 15-30 minutes at 55° C., and then precipitated with 4 mL MeOH. The last step was repeated one more time, and the resulting NQDs were dissolved in 0.2 mL n-butylamine+2 mL toluene and stored in this mixture for future use

Preparation of NQD/TiO₂ films. Nanocrystalline TiO₂ films were prepared using the procedure of Wang et al., “Enhance the Performance of Dye-Sensitized Solar Cells by Co-Grafting Amphiphilic Sensitizer and Hexadecylmalonic Acid on TiO₂ Nanocrystals”, J. Phys. Chem. B 2003, 107, 14336-14341, such reference incorporated herein by reference. For the optical measurements the films were deposited on 1 mm thick glass slides (Marathon Glass), while for the devices the films were deposited onto 1 mm Fluorine doped tin oxide coated glass (F—SnO₂ glass). Following the deposition the films were sintered at 500° C. to remove organic components. The thickness of the films was determined by step-profilometry using Alpha Step 500 TENCOR INSTRUMENTS) profilometer. The NQD/TiO₂ films were prepared by exposing freshly sintered TiO₂ to a solution of TOPO capped CdSe NQDs in hexane, or n-butylamine capped CdSe NQDs in toluene under argon atmosphere. It was noted that the deposition of TOPO-capped NQDs onto TiO₂ from toluene solution was significantly less efficient than deposition of NQD(TOPO) from hexane or NQD(BA) from toluene as evidenced by absorption and LHE measurements. Unless, stated otherwise in text the typical exposure time was 48 hours. The NQD/TiO₂ films were washed twice with the appropriate solvent and were allowed to dry under argon. Dry films were stored in dark in glove box under argon atmosphere until use.

Fabrication of PECs. The NQD based solar cells were fabricated using a two-electrode sandwich cell configuration similar to standard DSSCs arrangement. A platinum-coated F—SnO₂ glass was used as the counter electrode (CE). The two electrodes (a NQD/TiO₂ film on a F—SnO2 glass and CE) were separated by a Surlyn spacer (40-50 μm thick, Du Pont) and sealed by heating the polymer frame. The cell was filled with electrolyte (aqueous 1M Na₂S or Li₂S) using capillary action.

PEC Devices Characterization. The IPCE measurements were performed using QE/IPCE Measurement Kit equipped with 150 W Xe lamp (#6253 NEWPORT) as a light source and ORIEL CORNERSTONE #260 ¼ m Monochromator. The light intensity was adjusted with series of neutral density filters and monitored with NEWPORT Optical power meter 1830C power meter with calibrated Si power meter, NEWPORT model 818 UV. The photocurrent generated by the device was using KEITHLEY 6517A electrometer. Current voltage (I-V) measurements were performed using the same experimental arrangement. To irradiate the sample with a broadband white light instead of monochromatic light the grating in the monochromator was substituted with a manufacturer supplied high reflectivity broadband silver mirror. A black mask (0.2209 cm²) was attached to the solar cells in order to prevent irradiation with a scattered light. For both type of measurements the communication between the instruments and the computer was facilitated via a GPIB interface and the instrument control and data processing were performed using software written locally in LABVIEW.

The optical properties of CdSe NQD/TiO₂ composite films and their applications in PECs have been investigated. Results showed that the reduction in the size of the NQD surface capping ligand can lead to a significant enhancement in the LHE of the composite films due to more efficient coverage of the TiO₂ surface. Similarly, the use of shorter n-butylamine capping ligands leads to a significant enhancement of the performance of the PECs compared to the devices utilizing NQDs capped with tri-n-octylphosphine oxide. The enhancement in IPCE can be attributed to the improvement in both charge injection and charge collection efficiencies in devices utilizing n-butylamine capped NQDs.

All documents cited in the Detailed Description of the Invention are, in relevant part, incorporated herein by reference; the citation of any document is not to be construed as an admission that it is prior art with respect to the present invention. To the extent that any meaning or definition of a term in this document conflicts with any meaning or definition of the same term in a document incorporated by reference, the meaning or definition assigned to that term in this document shall govern.

Whereas particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. An article comprising:
a substrate,
a metal oxide film on the substrate,
quantum dots on the metal oxide film, the quantum dots further comprising ligands attached to the quantum dots, the ligands are primary amines having the formula RNH₂.

2. The article of claim 1, wherein the metal oxide comprises a transition metal.

3. The article of claim 2, wherein the metal oxide is a mixed metal oxide.

4. The article of claim 1, wherein the metal oxide comprises a dopant.

5. The article of claim 1, wherein the metal oxide is selected from titanium oxide (TiO₂), tin oxide (SnO₂), zinc oxide (ZnO), tungsten oxide (WO₃), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

6. The article of claim 1, wherein R is selected from R is propyl, butyl, pentyl, hexyl, heptyl, allyl, phenyl, and benzyl.

7. The article of claim 1, wherein the quantum dots are selected from cadmium sulfide, cadmium selenide, cadmium telluride, zinc sulfide, zinc selenide, zinc telluride, indium arsenide, indium phosphide, indium antimonide, and zinc cadmium selenide.

8. An article comprising:
a substrate;
a metal oxide film on the substrate,
quantum dots on the metal oxide film, the quantum dots further comprising ligands attached to the quantum dots, the ligands being primary amines having a size less than the size of tri-n-octylphosphine oxide.

9. The article of claim 8, wherein the metal oxide comprises a transition metal.

10. The article of claim 9, wherein the metal oxide is a mixed metal oxide.

11. The article of claim 8, wherein the metal oxide comprises a dopant.

12. The article of claim 8, wherein the metal oxide is selected from titanium oxide (TiO₂), tin oxide (SnO₂), zinc oxide (ZnO), tungsten oxide (WO₃), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

13. The article of claim 8, wherein the quantum dots are selected from cadmium sulfide, cadmium selenide, cadmium telluride, zinc sulfide, zinc selenide, zinc telluride, indium arsenide, indium phosphide, indium antimonide, and zinc cadmium selenide

14. A photoelectrochemical solar cell (PEC) comprising:
a photoanode comprising:
an electrically conducting substrate; and
a nanocrystalline film of a metal oxide on the electrically conducting substrate, the nanocrystalline film having a defined pore structure therein and further having pre-formed nano crystalline quantum dots (NQD) within said pore structure, said pre-formed NQDs having an organic passivating ligands that are primary amines attached to the NQDs,
a counter electrode, and
an electrolyte in contact with both the photoanode and the counter electrode.

15. The photoelectrochemical solar cell of claim 14, wherein the electrically conducting substrate is fluorine-doped tin oxide on glass.

16. The photoelectrochemical cell of claim 14, wherein the primary amines have a size less than the size of tri-n-octylphosphine oxide.

17. The photoelectrochemical cell of claim 14, wherein the electrolyte is selected from alkali metal sulfides.

18. The photoelectrochemical cell of claim 14, wherein the amine is a primary amine has the formula RNH₂ wherein R is selected from propyl, butyl, pentyl, hexyl, heptyl, allyl, phenyl, and benzyl.

19. The photoelectrochemical cell of claim 14, wherein the oxide is a transition metal oxide.

20. The photoelectrochemical cell of claim 14, wherein the oxide is selected from titanium oxide (TiO₂), tin oxide (SnO₂), zinc oxide (ZnO), tungsten oxide (WO₃), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

21. The photoelectrochemical cell of claim 14, wherein the quantum dots are selected from cadmium sulfide, cadmium selenide, cadmium telluride, zinc sulfide, zinc selenide, zinc telluride, indium arsenide, indium phosphide, indium antimonide, and zinc cadmium selenide.

22. The photoelectrochemical cell of claim 14, wherein the metal oxide film has more than two layers comprising a light absorbing layer and a light scattering layer.
